(19) United States
(12) Patent Application Publication
(10) Pub. No.: US 2018/0226202 A1
(43) Pub. Date: Aug. 9, 2018

(54) LIGHT-ABSORBING MATERIAL CONTAINING PEROVSKITE COMPOUND AND PEROVSKITE SOLAR CELL INCLUDING THE SAME

(71) Applicant: Panasonic Intellectual Property Management Co., Ltd., Osaka (JP)

(72) Inventors: TOMOYASU YOKOYAMA, Osaka (JP); MICHIO SUZUKA, Kyoto (JP); YOSHIKO MIYAMOTO, Osaka (JP); RYUUSUKE UCHIDA, Osaka (JP)

(21) Appl. No.: 15/887,983

(22) Filed: Feb. 3, 2018

(30) Foreign Application Priority Data
Feb. 7, 2017 (JP) 2017-020734

(51) Int. Cl. H01G 9/20; H01L 51/00; C07F 7/24

(52) U.S. Cl. CPC H01G 9/2059; H01L 51/4253; C07F 7/24; H01L 51/0077

(57) ABSTRACT

A light-absorbing material contains a perovskite compound represented by the composition formula CH₃NH₃PbI₃. The ¹H-NMR spectrum, which is obtained by ¹H-¹⁴N HMQC measurement, of the perovskite compound shows a first peak of 6.2 ppm and a second peak of 6.4 ppm at 25° C., and the peak intensity of the first peak is 15% or more of the peak intensity of the second peak.

### BACKGROUND

### 1. Technical Field

The present disclosure relates to a light-absorbing material and a perovskite solar cell produced from the light-absorbing material.

### 2. Description of the Related Art

In recent years, research and development have been conducted on perovskite solar cells produced by using perovskite crystals represented by the composition formula AMX₃ (A denotes a monovalent cation, M denotes a divalent cation, and X denotes a halogen anion) and their similar structures (hereinafter referred to as “perovskite compounds”) as light-absorbing materials.

Jeong-Hyeok Im, et al., Nature Nanotechnology (U.S.A.), November 2014, vol. 9, pp. 927-932 described the use of a perovskite compound represented by CH₃NH₃PbI₃ (hereinafter sometimes abbreviated as “MAPbI₃”) as a light-absorbing material for a perovskite solar cell.

There is a demand for perovskite solar cells with higher conversion efficiency.

### SUMMARY

One non-limiting and exemplary embodiment provides a light-absorbing material that can increase the conversion efficiency of a perovskite solar cell.

In one general aspect, the techniques disclosed here feature a light-absorbing material comprising: a perovskite compound represented by the composition formula CH₃NH₃PbI₃. The ¹H nuclear magnetic resonance (¹H-NMR) spectrum, which is obtained by ¹H-¹⁴N heteronuclear multiple quantum coherence (¹H-¹⁴N HMQC) measurement, of the perovskite compound shows a first peak of 6.2 ppm and a second peak of 6.4 ppm at 25° C., and the peak intensity of the first peak is 15% or more of the peak intensity of the second peak.

One embodiment of the present disclosure can provide a light-absorbing material that can increase the conversion efficiency of a perovskite solar cell.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic process drawing illustrating a method for producing a perovskite compound for use in a light-absorbing material according to an embodiment of the present disclosure;

FIG. 1B is a schematic process drawing illustrating a method for producing a perovskite compound for use in a light-absorbing material according to an embodiment of the present disclosure;

FIG. 1C is a schematic process drawing illustrating a method for producing a perovskite compound for use in a light-absorbing material according to an embodiment of the present disclosure;

FIG. 2 is a schematic cross-sectional view of a solar cell according to an embodiment of the present disclosure;

FIG. 3 is a schematic cross-sectional view of a solar cell according to another embodiment of the present disclosure;

FIG. 4 is a schematic cross-sectional view of a solar cell according to still another embodiment of the present disclosure;

FIG. 5 is a schematic cross-sectional view of a solar cell according to still another embodiment of the present disclosure;

FIG. 6 shows X-ray diffraction patterns of perovskite compounds according to Example 1 and Comparative Example 1;

FIG. 7A is a ¹H-¹⁴N HMQC solid-state ¹H-NMR spectrum in two-dimensional NMR of the perovskite compound according to Example 1;

FIG. 7B is a ¹H-¹⁴N HMQC solid-state ¹H-NMR spectrum in two-dimensional NMR of the perovskite compound according to Comparative Example 1;

FIG. 8A illustrates a crystal structure with a different bonding direction of an organic molecule in a perovskite compound;

FIG. 8B illustrates another crystal structure with a different bonding direction of an organic molecule in a perovskite compound;

FIG. 8C illustrates still another crystal structure with a different bonding direction of an organic molecule in a perovskite compound;

FIG. 8D illustrates still another crystal structure with a different bonding direction of an organic molecule in a perovskite compound;

FIG. 8E illustrates still another crystal structure with a different bonding direction of an organic molecule in a perovskite compound;

FIG. 9 is a graph showing the relationship between ¹H-NMR chemical shift and total energy calculated by first principle calculation for different bonding directions of an organic molecule in a perovskite compound;

FIG. 10A shows absorption spectra of the perovskite compounds according to Example 1 and Comparative Example 1;

FIG. 10B shows fluorescence spectra of the perovskite compounds according to Example 1 and Comparative Example 1;

FIG. 11 is a graph showing the relationship between ¹H-NMR chemical shift and bandgap calculated by first principle calculation for different bonding directions of an organic molecule in a perovskite compound; and

FIG. 12 is a graph showing the external quantum efficiency of perovskite solar cells according to Example 2 and Comparative Example 2.

### DETAILED DESCRIPTION

### <Underlying Knowledge Forming Basis of the Present Disclosure>

It is known that the conversion efficiency of a solar cell depends on the bandgap of a light-absorbing material to be used. For details, see W. Shockley et al., “Detailed balance limit of efficiency of p-n junction solar cells”, Journal of Applied Physics, vol. 32, no. 3, pp. 510-519 (1961). The conversion efficiency limit is known as the Shockley-Queisser limit. The theoretical conversion efficiency of a solar cell reaches its maximum when the solar cell is produced from a light-absorbing material with a bandgap of 1.4 eV. If the light-absorbing material has a bandgap of more than 1.4 eV, the open-circuit voltage can be increased, but the current value is decreased due to a shorter absorption wavelength. On the other hand, if the light-absorbing material has a bandgap of less than 1.4 eV, the current value can be increased due to a longer absorption wavelength, but the open-circuit voltage is decreased.

However, known perovskite compounds have a bandgap much higher than or much lower than the bandgap at which the theoretical efficiency reaches its maximum, that is, 1.4 eV. For example, CH₃NH₃PbI₃ has a bandgap of 1.59 eV. Thus, there is a demand for a perovskite compound with a bandgap of 1.4 eV or closer to 1.4 eV. The use of such a perovskite compound as a light-absorbing material for solar cells can increase conversion efficiency compared with known solar cells.

On the basis of the first principle calculation results, Carlo Motta et al. reported in Nature Communications., 2015, 6, 7026 that a change in the bonding direction of the MA cation in MAPbI₃ converts MAPbI₃ from a direct transition semiconductor to an indirect transition semiconductor and decreases the bandgap of MAPbI₃. Motta et al. explains that a change in the hydrogen bond strength between the H atoms bonded to the N atom in the MA cation and I⁻ alters the interaction strength between PbI₆ octahedrons, which is responsible for the decreased bandgap of MAPbI₃.

On the basis of the neutron diffraction results, Mark T. Weller et al. reported in Chem. Commun., 2015, 51, 4180-4183 that the MA cation in MAPbI₃ rotates at room temperature and tends to be oriented in a particular direction.

On the basis of the first principle calculation results, L. Leppert, et al. reported in J. Phys. Chem. Lett., 2016, 7, 3683-3689 that the orientation of the MA cation in MAPbI₃ in a single direction distorts the PbI₆ octahedron and increases the bandgap of MAPbI₃.

Thus, it has been suggested that a change in the bonding state of the MA cation in MAPbI₃ decreases the bandgap of MAPbI₃. However, MAPbI₃ with a different MA cation bonding state is energetically unstable and is not produced.

In view of these considerations, as a result of repeated investigations, the present inventor has found a novel MAPbI₃ perovskite compound with a smaller bandgap than before.

### <Summary of Aspect of Present Disclosure>

A light-absorbing material according to a first aspect of the present disclosure contains a perovskite compound represented by the composition formula CH₃NH₃PbI₃, having a perovskite structure, and having the peak intensity at 6.2 ppm equal to 15% or more of the peak intensity at 6.4 ppm at 25° C. in a ¹H-¹⁴N HMQC solid-state ¹H-NMR spectrum in two-dimensional NMR.

The light-absorbing material according to the first aspect can absorb light in a wider wavelength range when the organic molecule in the perovskite compound has a metastable bonding state. Thus, the light-absorbing material according to the first aspect can increase the conversion efficiency of a perovskite solar cell.

In a second aspect, for example, the light-absorbing material according to the first aspect may mainly contain the perovskite compound.

The light-absorbing material according to the second aspect can increase the conversion efficiency of a perovskite solar cell.

A light-absorbing material according to a third aspect of the present disclosure contains a perovskite compound represented by the composition formula CH₃NH₃PbI₃, having a perovskite structure, and having a spin-lattice relaxation time T1 in the range of 15 to 21 seconds at 25° C. as measured by solid-state ¹H-NMR spectroscopy.

The light-absorbing material according to the third aspect can stabilize the metastable bonding state of the organic molecule in the perovskite compound and can absorb light in a wider wavelength range. Thus, the light-absorbing material according to the third aspect can increase the conversion efficiency of a perovskite solar cell.

In a fourth aspect, for example, the light-absorbing material according to the third aspect may mainly contain the perovskite compound.

The light-absorbing material according to the fourth aspect can increase the conversion efficiency of a perovskite solar cell.

A perovskite solar cell according to a fifth aspect of the present disclosure includes a first electrode, a second electrode, and a light-absorbing layer disposed between the first electrode and the second electrode. The light-absorbing layer contains the light-absorbing material according to at least one of the first to fourth aspects.

The perovskite solar cell according to the fifth aspect can have increased conversion efficiency due to the light-absorbing material according to at least one of the first to fourth aspects contained in the light-absorbing layer.

### EMBODIMENTS OF PRESENT DISCLOSURE

Embodiments of the present disclosure will be described in detail below with reference to the accompanying drawings. These embodiments are only examples, and the present disclosure is not limited to these embodiments.

### First Embodiment

A light-absorbing material according to a first embodiment of the present disclosure will be described below. The following is the outline of a light-absorbing material according to the present disclosure. Two embodiments (embodiments A and B) of a light-absorbing material according to the present disclosure will be described below.

A light-absorbing material according to the embodiment A of the present disclosure contains a perovskite compound represented by the composition formula CH₃NH₃PbI₃, having a perovskite structure, and having the peak intensity at 6.2 ppm equal to 15% or more of the peak intensity at 6.4 ppm at 25° C. in a ¹H-¹⁴N HMQC solid-state ¹H-NMR spectrum in two-dimensional NMR. Such a perovskite compound is hereinafter also referred to as a “perovskite compound according to the embodiment A”.

The perovskite compound according to the embodiment A has a perovskite structure represented by AMX₃ in which CH₃NH₃⁺ is located at the A site, Pb²⁺ is located at the M site, and I⁻ is located at the X site.

The light-absorbing material according to the embodiment A may mainly contain the perovskite compound according to the embodiment A. The phrase “the light-absorbing material according to the embodiment A mainly contains the perovskite compound according to the embodiment A”, as used herein, means that the perovskite compound according to the embodiment A constitutes 90% or more by mass, for example, 95% or more by mass, of the light-absorbing material, or the light-absorbing material may be composed entirely of the perovskite compound according to the embodiment A.

The light-absorbing material according to the embodiment A may contain impurities as long as the light-absorbing material contains the perovskite compound according to the embodiment A. The light-absorbing material according to the embodiment A may contain another compound other than the perovskite compound according to the embodiment A.

MAPbI₃ has a crystal structure that includes a MA cation as an organic molecule in a lattice formed by sharing the lattice points of a PbI₆ octahedron. The organic molecule has an energetically stable bonding direction (hereinafter referred to as a particular direction) and is bonded to the PbI₆ octahedron in the particular direction. The particular direction is not one direction and includes symmetrical directions. The organic molecules are randomly oriented in these directions at room temperature. The bandgap of MAPbI₃ can be controlled by stabilizing a bonding direction different from the particular direction, that is, a bonding state that is not energetically most stable (hereinafter referred to as a “metastable state”) and thereby distorting the PbI₆ octahedron. In one example of the metastable state, the organic molecules are bonded (hereinafter referred to as “oriented”) in the same direction.

The perovskite compound according to the embodiment A can stabilize the metastable state of the organic molecule, decrease the bandgap, and absorb light in a wide wavelength range. Thus, the perovskite compound according to the embodiment A is useful as a light-absorbing material.

This means that a material with such characteristics can absorb light in a wider wavelength range when the organic molecule is metastably bonded.

As described above, in the perovskite compound according to the embodiment A, the peak intensity at 6.2 ppm at 25° C. in a ¹H-¹⁴N HMQC solid-state ¹H-NMR spectrum in two-dimensional NMR may be 15% or more, for example, 30% or more, of the peak intensity at 6.4 ppm. Furthermore, in the solid-state ¹H-NMR spectrum, the ratio of the peak intensity at 6.2 ppm to the peak intensity at 6.4 ppm may have any upper limit of less than 100%, for example, 90% or less.

A light-absorbing material according to the embodiment B of the present disclosure contains a perovskite compound represented by the composition formula CH₃NH₃PbI₃, having a perovskite structure, and having a spin-lattice relaxation time T1 in the range of 15 to 21 seconds at 25° C. as measured by solid-state ¹H-NMR spectroscopy. Such a perovskite compound is hereinafter also referred to as a “perovskite compound according to the embodiment B”.

Like the perovskite compound according to the embodiment A, the perovskite compound according to the embodiment B has a perovskite structure represented by AMX₃ in which CH₃NH₃⁺ is located at the A site, Pb²⁺ is located at the M site, and I⁻ is located at the X site.

The light-absorbing material according to the embodiment B may mainly contain the perovskite compound according to the embodiment B. The phrase “the light-absorbing material according to the embodiment B mainly contains the perovskite compound according to the embodiment B”, as used herein, means that the perovskite compound according to the embodiment B constitutes 90% or more by mass, for example, 95% or more by mass, of the light-absorbing material, or the light-absorbing material may be composed entirely of the perovskite compound according to the embodiment B.

The light-absorbing material according to the embodiment B may contain impurities as long as the light-absorbing material contains the perovskite compound according to the embodiment B. The light-absorbing material according to the embodiment B may contain another compound other than the perovskite compound according to the embodiment B.

As described above, the perovskite compound according to the embodiment B has a spin-lattice relaxation time T1 in the range of 15 to 21 seconds, which is longer than that of known MAPbI₃. The spin-lattice relaxation time corresponds to confining force in the compound or to activation energy for returning the bonding state of the compound to the most stable bonding state. More specifically, a longer spin-lattice relaxation time indicates more stable bonding in the compound. In general, an energetically unstable bonding state makes a transition to the most stable state. However, a stabilized bonding state has higher activation energy for transition and allows the metastable state to be maintained.

Having such characteristics, the perovskite compound according to the embodiment B can stabilize the bonding state of a metastable organic molecule.

This means that the perovskite compound according to the embodiment B can absorb light in a wider wavelength range.

The basic operational advantages of the light-absorbing materials according to the embodiments A and B will be described below.

### Physical Properties of Perovskite Compounds

The perovskite compounds according to the embodiments A and B can have the following physical properties (bandgap) useful as light-absorbing materials for solar cells.

The perovskite compounds according to the embodiments A and B can have a bandgap closer to 1.4 eV than the bandgap of known MAPbI₃ (1.59 eV).

The perovskite compounds according to the embodiments A and B may have a bandgap of 1.1 eV or more and less than 1.5 eV, for example, approximately 1.4 eV.

The bandgap of a perovskite compound can be calculated from the absorption edge wavelength determined in the absorbance measurement of the perovskite compound, for example.

The following is a possible reason why the perovskite compounds according to the embodiments A and B have long-wavelength absorption with a smaller bandgap than before.

As previously described, the MA cation in known MAPbI₃ perovskite compounds is oriented in an energetically stable particular bonding direction.

NMR measurement results suggest that the perovskite compounds according to the embodiments A and B contain the MA cation bonded in a metastable direction different from the stable bonding direction. The presence of the metastable MA cation distorts the PbI₆ octahedron and decreases the bandgap to approximately 1.48 eV. Thus, such light-absorbing materials for solar cells can have high efficiency.

### Method for Producing Light-Absorbing Material

A method for producing the perovskite compounds according to the embodiments A and B will be described below with reference to the accompanying drawings. The perovskite compounds according to the embodiments A and B can be produced by a solution coating method, a liquid phase epitaxy method, or a vapor deposition method. Although the liquid phase epitaxy method is described below, the method for producing the perovskite compounds according to the embodiments A and B is not limited to the liquid phase epitaxy method.

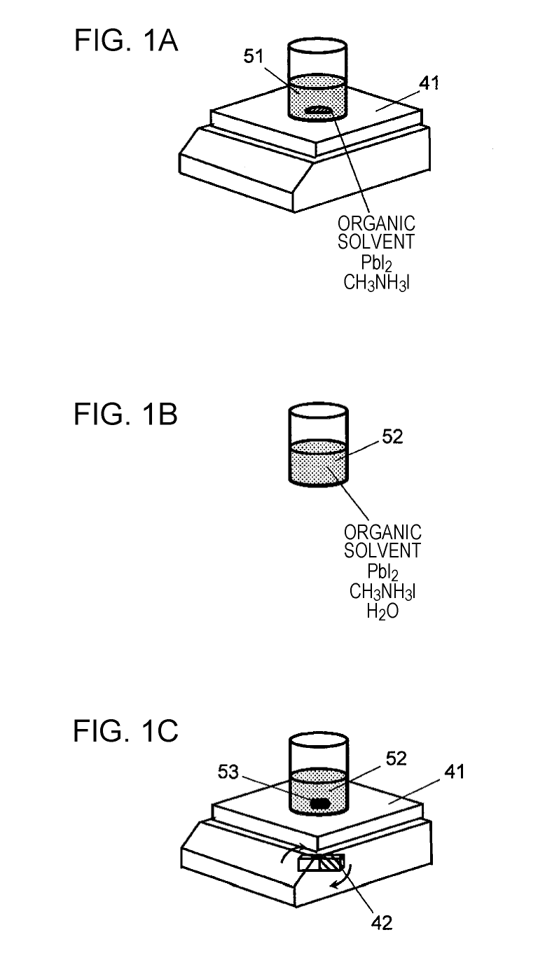

First, as illustrated in FIG. 1A, the same number of moles of PbI₂ and methyl ammonium iodide (MAI) CH₃NH₃₁ are added to an organic solvent. The organic solvent is selected from alcohols, lactones, alkyl sulfoxides, and amides and may be a mixture thereof. More specifically, the organic solvent may be γ-butyrolactone (γ-zBL), dimethyl sulfoxide (DMSO), and/or N,N-dimethylformamide.

The organic solvent containing PbI₂ and MAI is then heated on a hot plate 41 to a temperature in the range of 40° C. to 120° C. to dissolve PbI₂ and MAI in the organic solvent, thereby producing a yellow solution (a first solution 51). The first solution 51 is cooled to room temperature and is then mixed with pure water while vigorously stirring, thereby producing a second solution 52, as illustrated in FIG. 1B. The volume ratio of the pure water to the first solution 51 ranges from 0.1% to 1.0% by volume, for example. The second solution 52 is then left to stand (stored) at room temperature.

As illustrated in FIG. 1C, the second solution 52 is then left standing on the heated hot plate 41 in a rotating magnetic field of the magnet 42. Thus, black MAPbI₃ crystals 53 are precipitated in the second solution 52. The surface magnetic flux density of the magnetic field may be 0.1 T or more. The heating temperature may range from 80° C. to 200° C. In this temperature range, black MAPbI₃ can be easily precipitated as crystals with less solvent evaporation. An excessively low temperature may result in the formation of yellow MAPbI₃ with no perovskite structure. The standing time on the hot plate 41 (hereinafter referred to as the precipitation time) may range from 0.5 to 5 hours or 1 to 3 hours. The precipitation time in this range can satisfy both the ease of precipitation of black crystals and the suppression of phase transition to a non-perovskite structure due to a decreased amount of residual solvent in crystals. The crystals 53 are then thoroughly washed in acetone. In this manner, the perovskite compounds according to the embodiments A and B (MAPbI₃ crystals) can be produced.

### Second Embodiment

A perovskite solar cell according to a second embodiment of the present disclosure will be described below.

The solar cell according to the present embodiment includes a first electrode, a second electrode, and a light-absorbing layer disposed between the first electrode and the second electrode. The light-absorbing layer contains at least one of the light-absorbing materials according to the embodiments A and B of the first embodiment. The solar cell according to the present embodiment can have increased conversion efficiency due to at least one of the light-absorbing materials according to the embodiments A and B of the first embodiment. The structure of the solar cell according to the present embodiment and a method for producing the solar cell will be described below. Four structural examples (first to fourth examples) of the solar cell and methods for producing them will be described below with reference to the accompanying drawings.

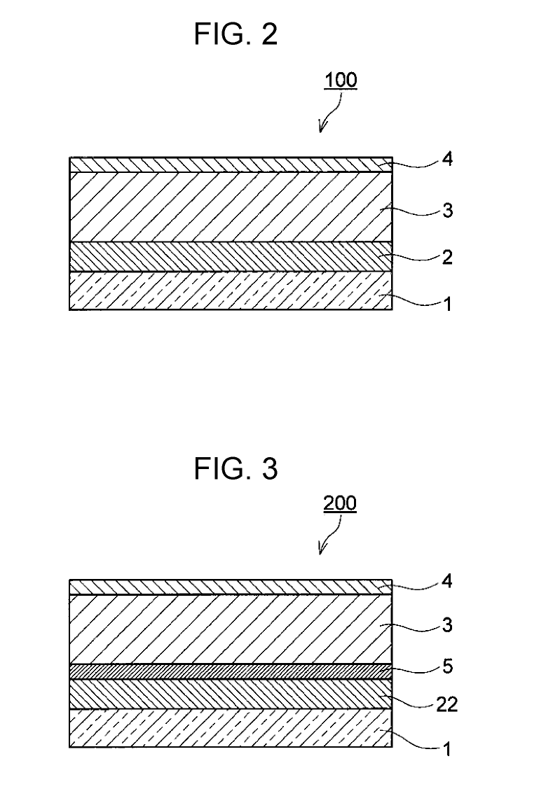

FIG. 2 is a schematic cross-sectional view of a solar cell 100 according to the first example of the present embodiment.

The solar cell 100 includes a first electrode 2, a light-absorbing layer 3, and a second electrode 4 in this order on a substrate 1. A light-absorbing material of the light-absorbing layer 3 contains the perovskite compound according to the first embodiment. The substrate 1 may be omitted in the solar cell 100.

Some basic operational advantages of the solar cell 100 will be described below. Upon irradiation of the solar cell 100 with light, the light-absorbing layer 3 absorbs light and generates excited electrons and positive holes. The excited electrons are transferred to the first electrode 2. The positive holes in the light-absorbing layer 3 are transferred to the second electrode 4. Thus, the solar cell 100 can generate an electric current from the first electrode 2 serving as a negative electrode and the second electrode 4 serving as a positive electrode.

The solar cell 100 can be produced by the following method, for example. First, the first electrode 2 is formed on the substrate 1 by a chemical vapor deposition method or a sputtering method, for example. The light-absorbing layer 3 is then formed on the first electrode 2. For example, a perovskite compound (MAPbI₃ crystals) produced by the method described above with reference to FIGS. 1A to 1C may be formed into the light-absorbing layer 3 with a predetermined thickness and may be placed on the first electrode 2. The second electrode 4 is then formed on the light-absorbing layer 3 to produce the solar cell 100.

The components of the solar cell 100 will be further described below.

### Substrate 1

The substrate 1 is an optional component. The substrate 1 supports the layers of the solar cell 100. The substrate 1 can be formed from a transparent material. For example, a glass substrate or a plastic substrate can be used. The plastic substrate may be a plastic film. If the first electrode 2 has sufficient strength, the first electrode 2 can support the layers without the substrate 1.

### First Electrode 2

The first electrode 2 is electrically conductive. The first electrode 2 does not form an ohmic contact with the light-absorbing layer 3. The first electrode 2 blocks the transfer of positive holes from the light-absorbing layer 3. Blocking the transfer of positive holes from the light-absorbing layer 3 means that only electrons generated in the light-absorbing layer 3 can pass through, and the positive holes cannot pass through. A material with such characteristics has a Fermi energy higher than the energy of the highest valence band of the light-absorbing layer 3. A material with a Fermi energy higher than the Fermi energy of the light-absorbing layer 3 may also be used. More specifically, aluminum may be used.

The first electrode 2 can transmit light. For example, the first electrode 2 can transmit light in the visible to near-infrared region. For example, the first electrode 2 can be formed of a transparent electrically conductive metal oxide. Examples of such a metal oxide include indium-tin composite oxides, tin oxides doped with antimony, tin oxides doped with fluorine, zinc oxides doped with at least one of boron, aluminum, gallium, and indium, and composites thereof.

The first electrode 2 may be formed of an opaque material by forming a light-transmitting pattern. The light-transmitting pattern may be a linear pattern, a wavy line pattern, a grid-like pattern, a punching metal pattern with many regularly or irregularly arranged fine through-holes, or a reverse pattern thereof. In the first electrode 2 with any of these patterns, light can pass through a portion not filled with the electrode material. Examples of the opaque electrode material include platinum, gold, silver, copper, aluminum, rhodium, indium, titanium, iron, nickel, tin, zinc, and alloys thereof. An electrically conductive carbon material may also be used.

The first electrode 2 may have a light transmittance of 50% or more or 80% or more. The wavelength of light to be transmitted depends on the absorption wavelength of the light-absorbing layer 3. The first electrode 2 may have a thickness in the range of 1 to 1000 nm.

### Light-Absorbing Layer 3

The light-absorbing layer 3 contains at least one of the light-absorbing materials according to the embodiments A and B of the first embodiment. More specifically, the light-absorbing material of the light-absorbing layer 3 contains at least one of the perovskite compounds according to the embodiments A and B of the first embodiment. The thickness of the light-absorbing layer 3 depends on the degree of optical absorption and ranges from 100 to 1000 nm, for example. As described above, the light-absorbing layer may be formed by cutting MAPbI₃ crystals. The light-absorbing layer 3 may be formed by any method. For example, the light-absorbing layer 3 may be formed by applying MAPbI₃ crystallites as seed crystals to a substrate (for example, the substrate 1 on which the first electrode 2 is formed in the solar cell 100 according to the first example) and immersing the substrate in a heated solution to grow crystals. The solution used in this method is the solution used in the production of the perovskite compound according to the first embodiment by the liquid phase epitaxy method as described in the first embodiment.

### Second Electrode 4

The second electrode 4 is electrically conductive. The second electrode 4 does not form an ohmic contact with the light-absorbing layer 3. The second electrode 4 blocks the transfer of electrons from the light-absorbing layer 3. Blocking the transfer of electrons from the light-absorbing layer 3 means that only positive holes generated in the light-absorbing layer 3 can pass through, and the electrons cannot pass through. A material with such characteristics has a Fermi energy lower than the energy of the lowest conduction band of the light-absorbing layer 3. A material with a Fermi energy lower than the Fermi energy of the light-absorbing layer 3 may also be used. More specifically, gold and carbon materials, such as graphene, may be used.

FIG. 3 is a schematic cross-sectional view of a solar cell 200 according to the second example of the present embodiment. The solar cell 200 includes an electron-transport layer and is different on this point from the solar cell 100 illustrated in FIG. 2. Components with the same function and structure as in the solar cell 100 are denoted by the same reference numerals and will not be further described.

The solar cell 200 includes a first electrode 22, an electron-transport layer 5, a light-absorbing layer 3, and a second electrode 4 in this order on a substrate 1. The substrate 1 may be omitted in the solar cell 200.

Some basic operational advantages of the solar cell 200 will be described below. Upon irradiation of the solar cell 200 with light, the light-absorbing layer 3 absorbs light and generates excited electrons and positive holes. The excited electrons are transferred to the first electrode 22 through the electron-transport layer 5. The positive holes in the light-absorbing layer 3 are transferred to the second electrode 4. Thus, the solar cell 200 can generate an electric current from the first electrode 22 serving as a negative electrode and the second electrode 4 serving as a positive electrode.

The solar cell 200 includes the electron-transport layer 5. Thus, the first electrode 22 does not need to block the positive holes from the light-absorbing layer 3. This increases the choice of the material for the first electrode 22.

The solar cell 200 can be produced in the same manner as the solar cell 100 illustrated in FIG. 2. The electron-transport layer 5 can be formed on the first electrode 22 by a sputtering method.

The components of the solar cell 200 will be further described below.

### First Electrode 22

The first electrode 22 is electrically conductive. The first electrode 22 may have the same structure as the first electrode 2. In the solar cell 200, the first electrode 22 does not need to block the positive holes from the light-absorbing layer 3 due to the electron-transport layer 5. Thus, the material of the first electrode 22 may form an ohmic contact with the light-absorbing layer 3.

The first electrode 22 can transmit light. For example, the first electrode 2 can transmit light in the visible to near-infrared region. The first electrode 2 can be formed of a transparent electrically conductive metal oxide. Examples of such a metal oxide include indium-tin composite oxides, tin oxides doped with antimony, tin oxides doped with fluorine, zinc oxides doped with at least one of boron, aluminum, gallium, and indium, and composites thereof.

The material for the first electrode 22 may be an opaque material. In this case, in the same manner as in the first electrode 2, the first electrode 22 has a light-transmitting pattern. Examples of the opaque electrode material include platinum, gold, silver, copper, aluminum, rhodium, indium, titanium, iron, nickel, tin, zinc, and alloys thereof. An electrically conductive carbon material may also be used.

The first electrode 22 may have a light transmittance of 50% or more or 80% or more. The wavelength of light to be transmitted depends on the absorption wavelength of the light-absorbing layer 3. The first electrode 22 may have a thickness in the range of 1 to 1000 nm.

### Electron-Transport Layer 5

The electron-transport layer 5 contains a semiconductor. The electron-transport layer 5 may be a semiconductor with a bandgap of 3.0 eV or more. The electron-transport layer 5 formed of a semiconductor with a bandgap of 3.0 eV or more can transmit visible light and infrared light to the light-absorbing layer 3. The semiconductor may be an organic or inorganic n-type semiconductor.

Examples of the organic n-type semiconductor include imide compounds, quinone compounds, and fullerenes and their derivatives. Examples of the inorganic n-type semiconductor include oxides of metal elements and perovskite oxides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, Si, and Cr. More specifically, TiO₂ may be used. Examples of the perovskite oxides include SrTiO₃ and CaTiO₃.

The electron-transport layer 5 may be formed of a substance with a bandgap of more than 6.0 eV. The substance with a bandgap of more than 6.0 eV may be an alkali metal or alkaline-earth metal halide, such as lithium fluoride or calcium fluoride, an alkali metal oxide, such as magnesium oxide, or silicon dioxide. In this case, in order to ensure the electron-transport ability of the electron-transport layer 5, the electron-transport layer 5 has a thickness of 10 nm or less, for example.

The electron-transport layer 5 may include layers of different materials.

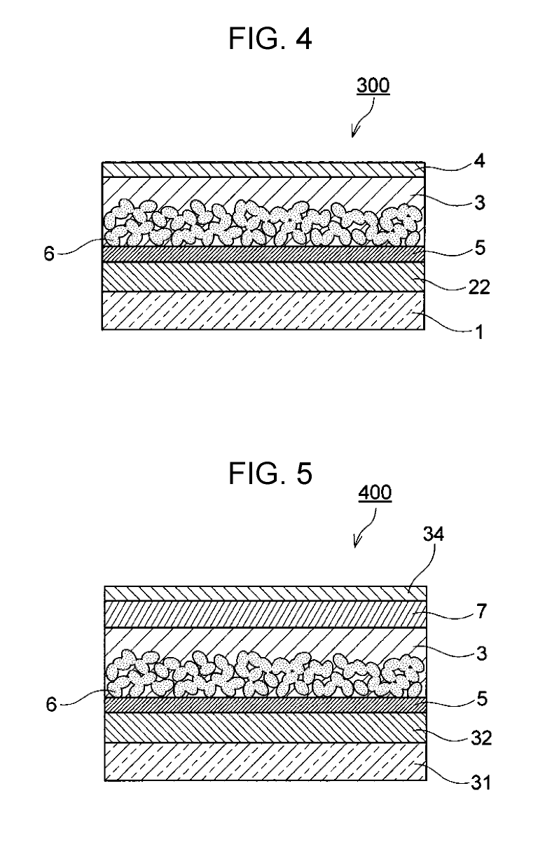

FIG. 4 is a schematic cross-sectional view of a solar cell 300 according to the third example of the present embodiment. The solar cell 300 includes a porous layer and is different on this point from the solar cell 200 illustrated in FIG. 3. Components with the same function and structure as in the solar cell 200 are denoted by the same reference numerals and will not be further described.

The solar cell 300 includes a first electrode 22, an electron-transport layer 5, a porous layer 6, a light-absorbing layer 3, and a second electrode 4 in this order on a substrate 1. The porous layer 6 includes a porous body. The porous body includes pores. The substrate 1 may be omitted in the solar cell 300.

The pores in the porous layer 6 communicate with the light-absorbing layer 3 and the electron-transport layer 5. Thus, the material of the light-absorbing layer 3 can fill the pores of the porous layer 6 and reach the electron-transport layer 5. Thus, the light-absorbing layer 3 is in contact with the electron-transport layer 5, and electrons can be directly transferred between the light-absorbing layer 3 and the electron-transport layer 5.

Some basic operational advantages of the solar cell 300 will be described below. Upon irradiation of the solar cell 300 with light, the light-absorbing layer 3 absorbs light and generates excited electrons and positive holes. The excited electrons are transferred to the first electrode 22 through the electron-transport layer 5. The positive holes in the light-absorbing layer 3 are transferred to the second electrode 4. Thus, the solar cell 300 can generate an electric current from the first electrode 22 serving as a negative electrode and the second electrode 4 serving as a positive electrode.

The porous layer 6 on the electron-transport layer 5 facilitates the formation of the light-absorbing layer 3. More specifically, the material of the light-absorbing layer 3 enters the pores of the porous layer 6, and the porous layer 6 serves as a scaffold of the light-absorbing layer 3. Thus, the material of the light-absorbing layer 3 is rarely repelled by the porous layer 6 or rarely aggregates.

Thus, the light-absorbing layer 3 can be uniformly formed. For example, the light-absorbing layer 3 in the solar cell 300 can be formed by applying MAPbI₃ crystallites as seed crystals to the porous layer 6 of a layered body composed of the substrate 1, the first electrode 22, the electron-transport layer 5, and the porous layer 6 and by immersing the layered body in a heated solution to grow the crystals. The solution used in this method is the solution used in the production of the perovskite compound according to the first embodiment by the liquid phase epitaxy method as described in the first embodiment.

The porous layer 6 is expected to scatter light and thereby increase the optical path length of light passing through the light-absorbing layer 3. The numbers of electrons and positive holes generated in the light-absorbing layer 3 will increase with the optical path length.

The solar cell 300 can be produced in the same manner as the solar cell 200. The porous layer 6 is formed on the electron-transport layer 5, for example, by a coating method.

### Porous Layer 6

The porous layer 6 serves as a base of the light-absorbing layer 3. The porous layer 6 does not block optical absorption in the light-absorbing layer 3 or electron transfer from the light-absorbing layer 3 to the electron-transport layer 5.

The porous layer 6 includes a porous body. The porous body may be composed of insulating or semiconductor particles. The insulating particles may be aluminum oxide or silicon oxide particles. The semiconductor particles may be inorganic semiconductor particles. Examples of the inorganic semiconductor include oxides of metal elements, perovskite oxides of metal elements, sulfides of metal elements, and metal chalcogenides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, Si, and Cr. More specifically, TiO₂ may be used. Examples of the perovskite oxides of metal elements include SrTiO₃ and CaTiO₃. Examples of the sulfides of metal elements include CdS, ZnS, In₂S₃, PbS, Mo₂S, WS₂, Sb₂S₃, Bi₂S₃, ZnCdS₂, and Cu₂S. Examples of the metal chalcogenides include CsSe, In₂Se₃, WSe₂, HgS, PbSe, and CdTe.

The porous layer 6 may have a thickness in the range of 0.01 to 10 μm or 0.1 to 1 μm. The porous layer 6 may have a rough surface. More specifically, the surface roughness factor given by the effective area/projected area ratio may be 10 or more or 100 or more. The projected area refers to the area of a shadow of an object illuminated with light from the front. The effective area refers to the actual surface area of the object. The effective area can be calculated from the volume determined from the projected area and thickness of the object and the specific surface area and bulk density of the material of the object. The specific surface area is measured by a nitrogen adsorption method, for example.

FIG. 5 is a schematic cross-sectional view of a solar cell 400 according to the fourth example of the present embodiment.

The solar cell 400 includes a hole-transport layer and is different on this point from the solar cell 300 illustrated in FIG. 4. Components with the same function and structure as in the solar cell 300 are denoted by the same reference numerals and will not be further described.

The solar cell 400 includes a first electrode 32, an electron-transport layer 5, a porous layer 6, a light-absorbing layer 3, a hole-transport layer 7, and a second electrode 34 in this order on a substrate 31. The substrate 31 may be omitted in the solar cell 400.

Some basic operational advantages of the solar cell 400 according to the present embodiment will be described below.

Upon irradiation of the solar cell 400 with light, the light-absorbing layer 3 absorbs light and generates excited electrons and positive holes. The excited electrons are transferred to the electron-transport layer 5. The positive holes in the light-absorbing layer 3 are transferred to the hole-transport layer 7. The electron-transport layer 5 is connected to the first electrode 32, and the hole-transport layer 7 is connected to the second electrode 34. Thus, the solar cell 400 can generate an electric current from the first electrode 32 serving as a negative electrode and the second electrode 34 serving as a positive electrode.

The solar cell 400 includes the hole-transport layer 7 between the light-absorbing layer 3 and the second electrode 34. Thus, the second electrode 34 does not need to block electrons from the light-absorbing layer 3. This increases the choice of the material for the second electrode 34.

The components of the solar cell 400 will be further described below. The same components as in the solar cell 300 will not be described here.

### First Electrode 32 and Second Electrode 34

As described above, the second electrode 34 does not need to block electrons from the light-absorbing layer 3. Thus, the material of the second electrode 34 may form an ohmic contact with the light-absorbing layer 3. Thus, the second electrode 34 can be formed to transmit light.

At least one of the first electrode 32 and the second electrode 34 can transmit light and has the same structure as the first electrode 2 of the solar cell 100.

One of the first electrode 32 and the second electrode 34 does not need to transmit light. Thus, a light-transmitting material or a pattern with an opening portion for transmitting light is not necessarily required.

### Substrate 31

The substrate 31 can have the same structure as the substrate 1 of the solar cell 100 illustrated in FIG. 2. If the second electrode 34 can transmit light, the material for the substrate 31 may be opaque. For example, the material for the substrate 31 may be a metal, a ceramic, or a resin material with low optical transparency.

### Hole-Transport Layer 7

The hole-transport layer 7 is formed of an organic substance or an inorganic semiconductor, for example. The hole-transport layer 7 may include layers of different materials.

The hole-transport layer 7 may have a thickness in the range of 1 to 1000 nm or 10 to 50 nm. This range results in satisfactory hole-transport characteristics. Furthermore, due to low resistance, highly efficient photovoltaic power generation is possible.

The hole-transport layer 7 can be formed by a coating method or a printing method. Examples of the coating method include a doctor blade method, a bar coating method, a spray method, a dip coating method, and a spin coating method. The printing method may be a screen printing method. If necessary, materials may be mixed to form the hole-transport layer 7 and may be pressed or baked. When the material for the hole-transport layer 7 is a low-molecular-weight organic material or an inorganic semiconductor, the hole-transport layer 7 can be formed by a vacuum deposition method.

The hole-transport layer 7 may contain a supporting electrolyte and a solvent. The supporting electrolyte and solvent can stabilize positive holes in the hole-transport layer 7.

Examples of the supporting electrolyte include ammonium salts and alkali metal salts. Examples of the ammonium salts include tetrabutylammonium perchlorate, tetraethylammonium hexafluorophosphate, imidazolium salts, and pyridinium salts. Examples of the alkali metal salts include lithium perchlorate and potassium tetrafluoroborate.

The solvent in the hole-transport layer 7 may have high ionic conductivity. The solvent in the hole-transport layer 7 may be an aqueous solvent or an organic solvent. An organic solvent may be used to further stabilize a solute. Specific examples include heterocyclic compound solvents, such as tert-butylpyridine, pyridine, and n-methylpyrrolidone.

The solvent may be an ionic liquid alone or a mixture of an ionic liquid and another solvent. An ionic liquid has low volatility and has flame retardancy.

Examples of the ionic liquid include imidazoliums, such as 1-ethyl-3-methylimidazolium tetracyanoborate, pyridines, alicyclic amines, aliphatic amines, and azonium amines.

### EXAMPLES

Perovskite compounds (hereinafter abbreviated as “compounds”) were produced in Examples and Comparative Examples, and the physical properties of the compounds were evaluated. The methods and results are described below. Solar cells were produced by using the perovskite compounds. The characteristics of the solar cells were also evaluated. The methods and results are also described below.

### Production of Compounds of Examples and Comparative Examples

### Example 1

A compound of Example 1 was produced by the method described above with reference to FIGS. 1A to 1C. More specifically, 1 mol/L PbI₂ (manufactured by Tokyo Chemical Industry Co., Ltd.) and 1 mol/L MAI (manufactured by Tokyo Chemical Industry Co., Ltd.) were dissolved in γ-butyrolactone (γ-zBL) on the hot plate 41 at 100° C., thereby producing a yellow solution (the first solution 51). The first solution 51 was then cooled to room temperature and was mixed with 0.7% by volume of pure water while vigorously stirring, thereby producing the second solution 52. The second solution 52 was then left standing on the hot plate 41 at 140° C. in a rotating magnetic field with a magnetic flux density of 0.3 T. The standing time was 3 hours. Black crystals 53 were precipitated in the second solution 52. The crystals were thoroughly washed in acetone to produce a compound (MAPbI₃ crystals) according to Example 1.

### Example 2

A glass substrate was used as a substrate. The glass substrate had ITO on its surface. A SnO₂ layer 20 nm in thickness was formed on the ITO by sputtering. The compound (MAPbI₃ crystals) according to Example 1 was cut with a diamond cutter into a sheet and was smoothed with a sandpaper to produce a sheet sample 200 μm in thickness. The sample was placed on the SnO₂ layer, and gold was deposited to a thickness of 80 nm on the sample. Thus, a solar cell was produced. The solar cell had the same structure as the solar cell 200 according to the second example described in the second embodiment (see FIG. 3). The solar cell according to Example 2 included the following components.

Substrate 1: glass

First electrode 22: ITO

Electron-transport layer 5: SnO₂ (20 nm in thickness)

Light-absorbing layer 3: the compound according to Example 1 (200 μm in thickness)

Second electrode 4: Au (80 nm in thickness)

### Comparative Example 1

First, a dimethyl sulfoxide (DMSO) solution containing 1 mol/L PbI₂ and 1 mol/L MAI was prepared. The solution was then applied to a substrate by spin coating. The substrate was a glass substrate 1 mm in thickness on which a fluorine-doped SnO₂ layer was formed (manufactured by Nippon Sheet Glass Co., Ltd.). The substrate was heated on a hot plate at 100° C. to produce a compound (MAPbI₃ film).

### Comparative Example 2

A MAPbI₃ film was formed on a substrate in the same manner as in Comparative Example 1. Gold was deposited to a thickness of 80 nm on the MAPbI₃ film. Thus, a solar cell was produced. As in Example 2, the substrate was a glass substrate with ITO on which a SnO₂ layer 20 nm in thickness was formed by sputtering.

### <Crystal Structure Analysis>

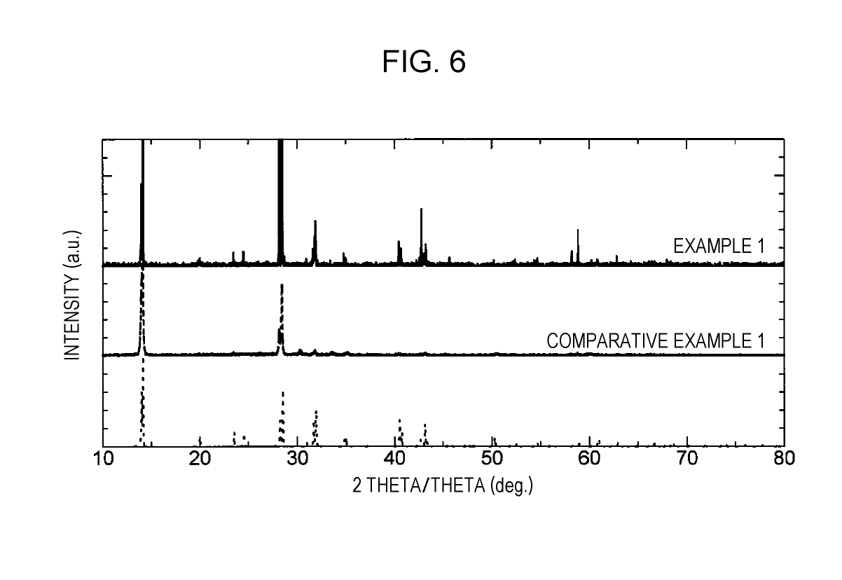

The compounds according to Example 1 and Comparative Example 1 were subjected to X-ray diffraction (XRD) with Cu-Kα radiation. FIG. 6 shows the XRD measurement results of Example 1 (solid line) and Comparative Example 1 (broken line). The horizontal axis represents 20, and the vertical axis represents X-ray diffraction intensity. The dotted lines at the bottom of FIG. 6 indicate the theoretical XRD pattern of MAPbI₃ with a tetragonal perovskite structure at room temperature. FIG. 6 shows that the compounds according to Example 1 and Comparative Example 1 had the perovskite structure.

### <Mobility Analysis>

The compounds according to Example 1 and Comparative Example 1 were subjected to mobility analysis. The spin-lattice relaxation time was measured by solid-state ¹H-NMR spectroscopy under the following conditions. The spin-lattice relaxation time is a measure of molecular mobility. The spin-lattice relaxation time indicates the bond strength between the MA cation and PbI₆ octahedron.

Apparatus: JNM-ECZ600R/M1 manufactured by JEOL Ltd.

Observed nuclear: ¹H

Measuring frequency: 600.172 MHz

Measurement temperature: 25° C.

Method of measurement: saturation recovery method

90-degree pulse width: 0.85 μs

Rotational speed of magic-angle spinning: 70 kHz

Waiting time for pulse application: 0.1 s

Number of scans: 64

The chemical shift was determined with respect to an external standard adamantane. In order to prevent deterioration caused by water in the air, a sample was placed in an airtight sample tube in a dry nitrogen stream in a dry atmosphere. The sample tube was 1 mm in diameter.

¹H-NMR measurement under these conditions showed a spectrum of the H atoms bonded to the N atom at 6.2 to 6.6 ppm. The relaxation time T1 was determined by fitting the peak intensity change at 6.2 to 6.6 ppm for different recovery times τ in pulse sequence to the following equation by the nonlinear least-squares method. M denotes the peak intensity.

$$M ( τ ) = M ( ∞ ) ( 1 - {e}^{- \frac{τ}{{T}_{1}}} )$$

Table 1 shows the results. Table 1 shows that the spin-lattice relaxation time was longer in Example 1 than in Comparative Example 1. This result shows that the bond strength between the MA cation and PbI₆ octahedron is stronger in Example 1 than in Comparative Example 1, suggesting that in Example 1 the PbI₆ octahedron confines the MA cation and restricts the molecular motion of the MA cation. The stronger force of the PbI₆ octahedron confining the MA cation increases the activation energy for returning to the most stable bonding state and stabilizes the metastable bonding state.

Thus, in the compound according to Example 1, the PbI₆ octahedron confines the MA cation and stabilizes the metastable bonding state, which does not exist in the compound according to Comparative Example 1.

TABLE 1

| | | Spin-lattice relaxation |
|---|---|---|
| | Peak position (ppm) | time (s) |
| Example 1 | 6.4 | 17.5 ± 2 |
| Comparative example 1 | 6.4 | 13.7 ± 1 |

### <Electronic State Analysis>

The compounds according to Example 1 and Comparative Example 1 were subjected to electronic state analysis. A ¹H-¹⁴N HMQC solid-state ¹H-NMR spectrum was measured by two-dimensional NMR under the following conditions. The measurement can determine the electronic state of only the H atoms bonded to the N atom.

Apparatus: JNM-ECZ600R/M1 manufactured by JEOL Ltd.

Observed nuclear: ¹H

Measuring frequency: 600.172 MHz

Measurement temperature: 25° C.

Method of measurement: magic-angle spinning (MAS)

Pulse sequence: ¹H-¹⁴N/HMQC

90-degree pulse width: 0.85 μs

Rotational speed of magic-angle spinning: 70 kHz

Waiting time for pulse application: 20 s

Number of scans: 64

The chemical shift was determined with respect to an external standard adamantane. In order to prevent deterioration caused by water in the air, a sample was placed in an airtight sample tube in a dry nitrogen stream in a dry atmosphere. The sample tube was 1 mm in diameter. The peaks were separated using the Voigt function.

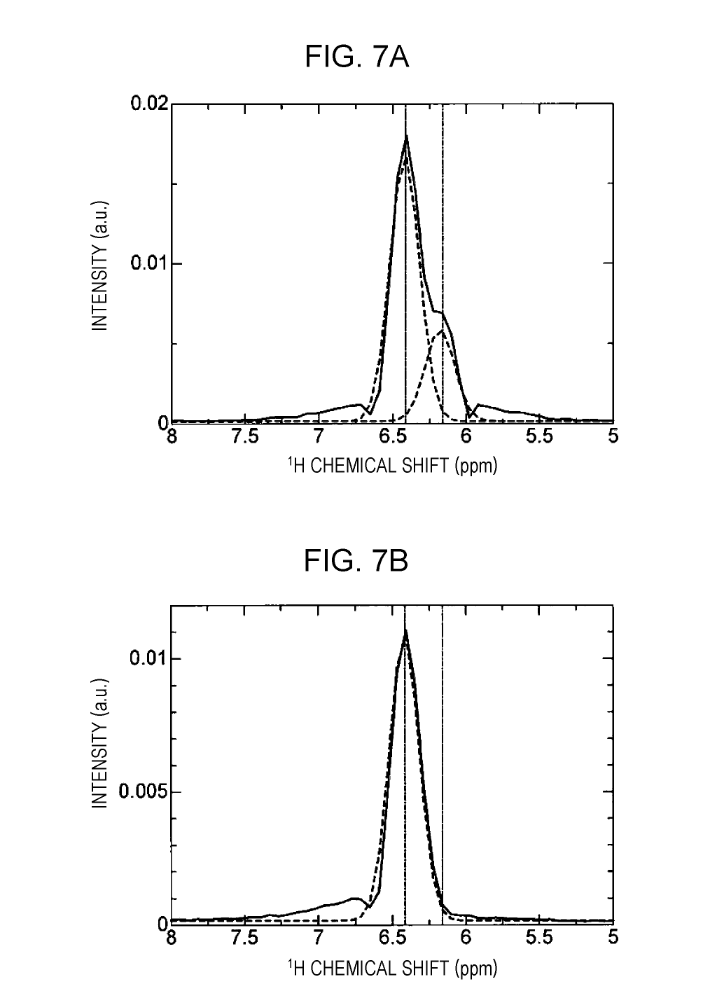

FIG. 7A shows the measurement results of Example 1, and FIG. 7B shows the measurement results of Comparative Example 1. The solid lines indicate the actual values, and the broken lines indicate the peak fitting results based on the actual measurements. Table 2 shows the peak fitting results of the NMR spectra. Example 1 includes a peak (6.2 ppm) not observed in Comparative Example 1 on the high magnetic field side in addition to a peak (6.4 ppm) observed in Comparative Example 1. The chemical shift to a higher magnetic field indicates that the bonding state is energetically metastable.

Table 3 shows the spectral intensity 16.2 at 6.2 ppm, the spectral intensity 16.4 at 6.4 ppm, and the intensity ratio 16.2/16.4 in Example 1 and Comparative Example 1. In Example 1, the spectral intensity at 6.2 ppm is 39% of the spectral intensity at 6.4 ppm, which is larger than 12% in Comparative Example 1.

The peaks in the measurement are assigned to the H atoms bonded to the N atom in the MA cation. The presence of the two peaks in Example 1 indicates the presence of the MA cation with another bonding state different from the bonding state in Comparative Example 1.

TABLE 2

| | | Full width at half maximum |
|---|---|---|
| | Peak top (ppm) | (ppm) |
| Example 1 | 6.2 | 0.22 |
| | 6.4 | 0.24 |
| Comparative example 1 | 6.4 | 0.25 |

TABLE 3

| | Peak | | |
|---|---|---|---|
| | intensity I_{6.2} | Peak intensity I_{6.4} | Intensity ratio I_{6.2}/I_{6.4} |
| Example 1 | 6.90 ± 0.3 | 17.8 ± 0.9 | 0.388 ± 0.03 |
| Comparative | 1.34 ± 0.07 | 11.0 ± 0.6 | 0.122 ± 0.02 |
| example 1 | | | |

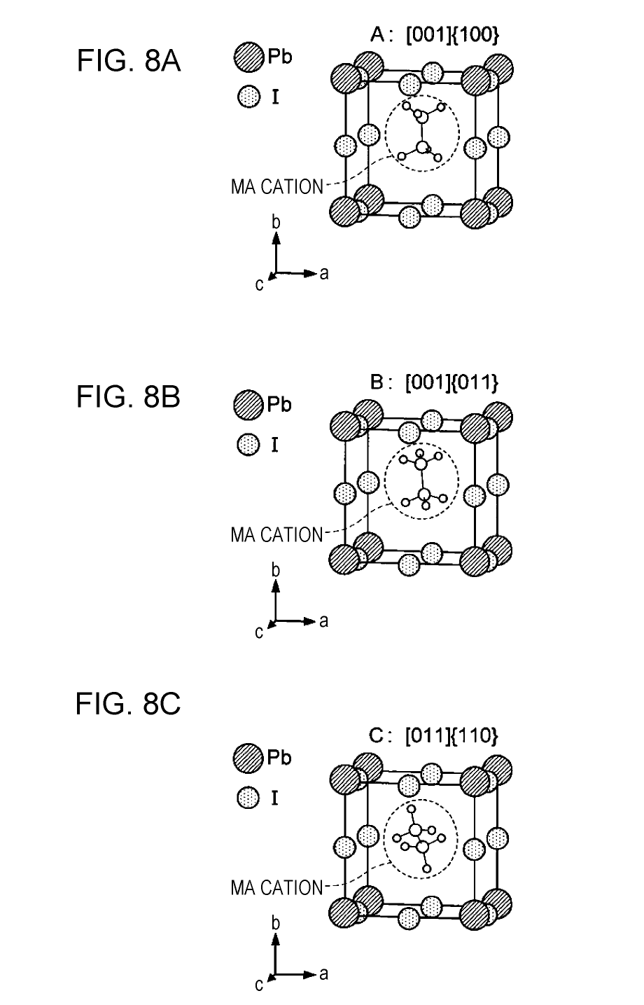

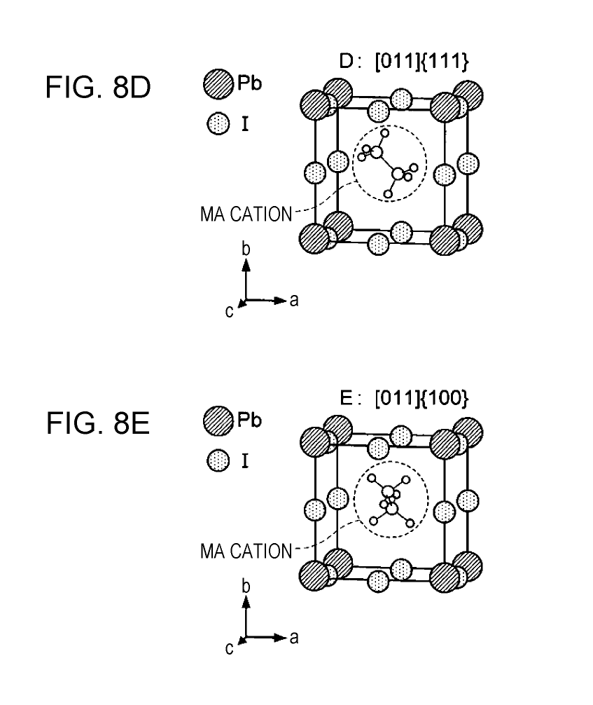

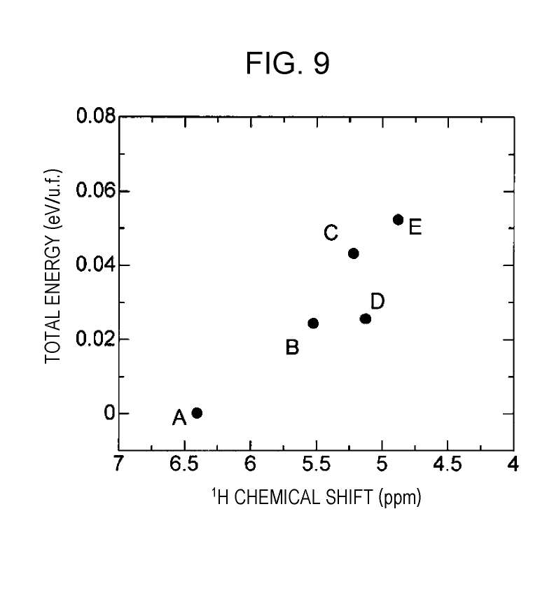

A chemical shift change in a ¹H-NMR spectrum due to a different bonding direction of the MA cation in MAPbI₃ was analyzed by first principle calculation. The MA cation exhibits polarization due to asymmetry of its molecule. Rotation of the MA cation in the crystal lattice changes the state of bonding to the PbI₆ octahedron. This changes the chemical shift in NMR measurement. FIGS. 8A to 8E illustrate the structures in which the MA cation in MAPbI₃ is rotated in different directions. The total energy of each structure of FIGS. 8A to 8E is plotted in FIG. 9, wherein the horizontal axis represents the average chemical shift of the H atoms bonded to the N atom, and the vertical axis represents the total energy.

FIG. 9 shows that a bonding direction in which the peak is located in a lower magnetic field tends to be energetically more stable. On the basis of the NMR measurements, the peak observed in both Comparative Example 1 and Example 1 corresponds to the state of the MA cation oriented in the energetically most stable bonding direction. The presence of the MA cation oriented in the metastable bonding direction in Example 1 results in the peak on the high magnetic field side not observed in Comparative Example 1. This suggests a decrease in the bandgap of MAPbI₃ and an increase in the absorption wavelength range.

This demonstrated that the compound according to Example 1 contains the metastable MA cation bonded in the direction that does not exist in the compound according to Comparative Example 1, in addition to the MA cation with the same bonding state as in the compound according to Comparative Example 1.

### <Measurement of Optical Characteristics>

The compounds according to Example 1 and Comparative Example 1 were subjected to absorbance measurement and fluorescence measurement, and the bandgap was calculated from absorption edge energy.

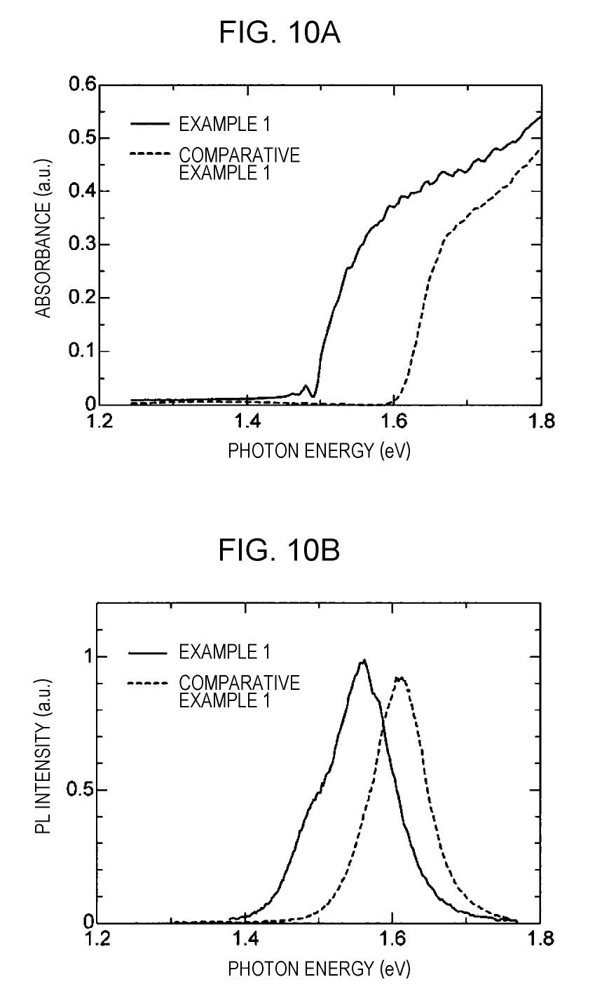

FIG. 10A shows the absorption spectra of the compounds according to Example 1 (solid line) and Comparative Example 1 (broken line). The horizontal axis represents photon energy, and the vertical axis represents absorbance. The figure shows that the absorption edge energy corresponding to the bandgap of the compound according to Comparative Example 1 is 1.60 eV. On the other hand, the absorption edge energy of the compound according to Example 1 is 1.48 eV. Thus, the absorption edge energy of the compound is located at a longer wavelength (lower energy) in Example 1 than in Comparative Example 1.

FIG. 10B shows the fluorescence spectra of the compounds according to Example 1 (solid line) and Comparative Example 1 (broken line) obtained by fluorescence measurement with a 532-nm laser light source. The horizontal axis represents photon energy, and the vertical axis represents fluorescence intensity. The figure shows that the fluorescence spectrum of the compound according to Comparative Example 1 has a peak at 1.61 eV. On the other hand, the fluorescence spectrum of the compound according to Example 1 has a peak at 1.48 eV in addition to the peak at 1.56 eV. Thus, the presence of the fluorescence peak at 1.48 eV demonstrated that the peak of the fluorescence spectrum is located at a longer wavelength (lower energy) in the compound according to Example 1 than in the compound according to Comparative Example 1.

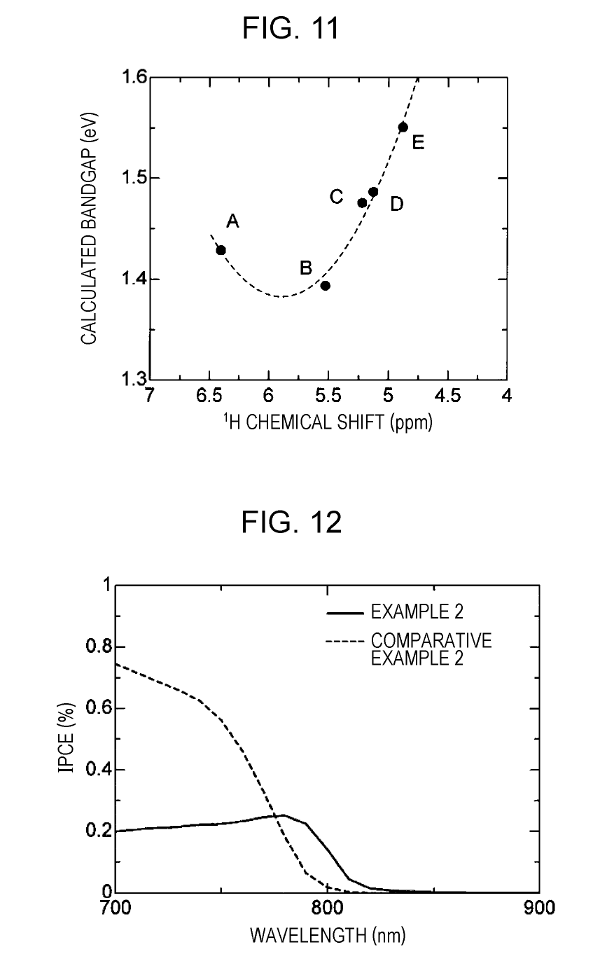

A bandgap change due to a different bonding direction of the MA cation in MAPbI₃ was analyzed by first principle calculation. FIG. 11 shows bandgaps when the MA cation in MAPbI₃ is rotated in different directions. The horizontal axis represents the average chemical shift of the H atoms bonded to the N atom, and the vertical axis represents the calculated bandgap. The alphabets in the figure correspond to the structures illustrated in FIGS. 8A to 8E. Calculated bandgaps generally tend to be smaller than experimental values, and the calculated bandgaps herein are also smaller than experimental values.

In FIG. 11, a minimum bandgap appears when the chemical shift changes from 6.4 ppm (a stable bonding direction) to the high magnetic field side. The compound according to Example 1, which has an NMR peak in a slightly higher magnetic field than in Comparative Example 1, has a smaller bandgap than the compound according to Comparative Example 1. This matches the tendency of the calculation.

Thus, absorption and emission at 1.48 eV by the compound according to Example 1 result from the metastable MA cation bonded in the direction that does not exist in the compound according to Comparative Example 1. Due to the presence of the metastable MA cation, the compound according to Example 1 has a bandgap close to the bandgap at which the theoretical efficiency reaches its maximum (approximately 1.4 eV) and can contribute to high conversion efficiency.

### <Characterization of Solar Cell>

The solar cells according to Example 2 and Comparative Example 2 were subjected to incident photon to current conversion efficiency (IPCE: quantum efficiency at each wavelength) measurement. The energy of the light source was 5 mW/cm² at each wavelength.

FIG. 12 shows the results of Example 2 (solid line) and Comparative Example 2 (broken line), wherein the vertical axis represents external quantum efficiency, and the horizontal axis represents wavelength. In FIG. 12, the actual values in Example 2 are multiplied by 30. Like Comparative Example 2, Example 2 also functions as a solar cell. Although the solar cell according to Comparative Example 2 has an absorption edge wavelength of 780 nm (equivalent to energy of 1.58 eV), the absorption wavelength range of the solar cell according to Example 2 extends to a longer wavelength (820 nm, equivalent to energy of 1.51 eV). Thus, in Example 2, carriers generated by optical absorption in the long-wavelength range shown by the optical measurement results are successfully taken out.

Thus, in the solar cell including the light-absorbing layer produced from the compound according to Example 1, the compound according to Example 1 can improve the conversion efficiency of the solar cell.

The present disclosure provides a light-absorbing material containing a novel perovskite compound, and the light-absorbing material used in a light-absorbing layer of a solar cell can improve the conversion efficiency of the solar cell. Thus, the light-absorbing material has very high industrial applicability.

What is claimed is:

1. A light-absorbing material comprising: a perovskite compound represented by a composition formula CH₃NH₃PbI₃, wherein
a ¹H-NMR spectrum, which is obtained by ¹H-¹⁴N HMQC measurement, of the perovskite compound shows a first peak of 6.2 ppm and a second peak of 6.4 ppm at 25° C., and
a peak intensity of the first peak is 15% or more of a peak intensity of the second peak.

2. The light-absorbing material according to claim 1, wherein the light-absorbing material mainly contains the perovskite compound.

3. A light-absorbing material comprising: a perovskite compound represented by a composition formula CH₃NH₃PbI₃, wherein
a spin-lattice relaxation time T1, which is obtained by solid-state ¹H-NMR spectroscopy, of the perovskite compound is within a range of 15 to 21 seconds at 25° C.

4. The light-absorbing material according to claim 3, wherein the light-absorbing material mainly contains the perovskite compound.

5. A perovskite solar cell comprising:
a first electrode;
a second electrode; and
a light-absorbing layer disposed between the first electrode and the second electrode,
wherein the light-absorbing layer contains the light-absorbing material according to claim 1.

6. A perovskite solar cell comprising:
a first electrode;
a second electrode; and
a light-absorbing layer disposed between the first electrode and the second electrode,
wherein the light-absorbing layer contains the light-absorbing material according to claim 3.
